(19) United States
(12) Patent Application Publication
(10) Pub. No.: US 2024/0136198 A1
(43) Pub. Date: Apr. 25, 2024

(54) SUBSTRATE-PROCESSING METHOD AND SUBSTRATE-PROCESSING APPARATUS

(71) Applicant: Tokyo Electron Limited, Tokyo (JP)

(72) Inventor: Rui KANEMURA, Yamanashi (JP)

(21) Appl. No.: 18/482,401

(22) Filed: Oct. 5, 2023

(30) Foreign Application Priority Data
Oct. 24, 2022 (JP) 2022-170499

(51) Int. Cl. H01L 21/311; H01L 21/67

(52) U.S. Cl. CPC H01L 21/31116; H01L 21/67069

(57) ABSTRACT

A substrate-processing method includes a) providing a substrate including a silicon oxide film on a surface of the substrate, b) supplying a gas mixture to the surface of the substrate, thereby etching the silicon oxide film, the gas mixture including fluorine-containing gas and basic gas, c) purging the surface of the substrate, and d) alternatingly repeating b) and c).

### CROSS-REFERENCE TO RELATED APPLICATIONS

This application is based upon and claims priority to Japanese Patent Application No. 2022-170499, filed on Oct. 25, 2022, the entire contents of which are incorporated herein by reference.

### BACKGROUND

### 1. Field of the Invention

The present disclosure relates to substrate-processing methods and substrate-processing apparatuses.

### 2. Description of the Related Art

In, for example, Japanese Laid-Open Patent Publication No. 2004-343094, a technique of removing a silicon oxide film using a gas mixture of hydrogen fluoride gas and ammonia gas is known.

### SUMMARY

According to one aspect of the present disclosure, a substrate-processing method includes a) providing a substrate including a silicon oxide film on a surface of the substrate, b) supplying a gas mixture to the surface of the substrate, thereby etching the silicon oxide film, the gas mixture including fluorine-containing gas and basic gas, c) purging the surface of the substrate, and d) alternatingly repeating b) and c).

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flowchart illustrating a substrate-processing method according to an embodiment;

FIG. 2 is a cross-sectional view illustrating one example of a substrate;

FIG. 3 is a cross-sectional view illustrating another example of the substrate;

FIG. 4 is a schematic view illustrating a substrate-processing apparatus according to an embodiment;

FIG. 5 is a graph illustrating evaluation results of etching amounts; and

FIG. 6 is a view illustrating a relationship between time of a COR step and etching amount.

### DETAILED DESCRIPTION

The present disclosure provides a technique that can increase selectivity etching ratio of a silicon oxide film with respect to a silicon nitride film.

Hereinafter, non-limiting embodiments of the present disclosure will be described with reference to the drawings. In the drawings, the same or corresponding members or components are designated by the same reference symbols, and duplicate description thereof will be omitted.

[Substrate-Processing Method]

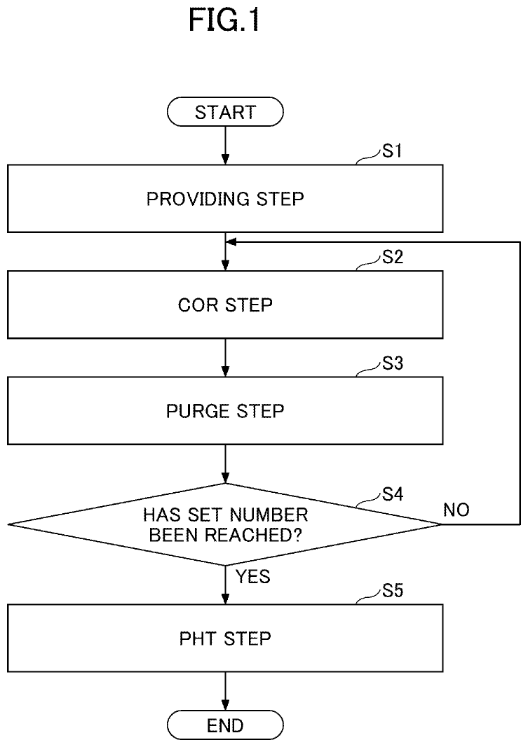

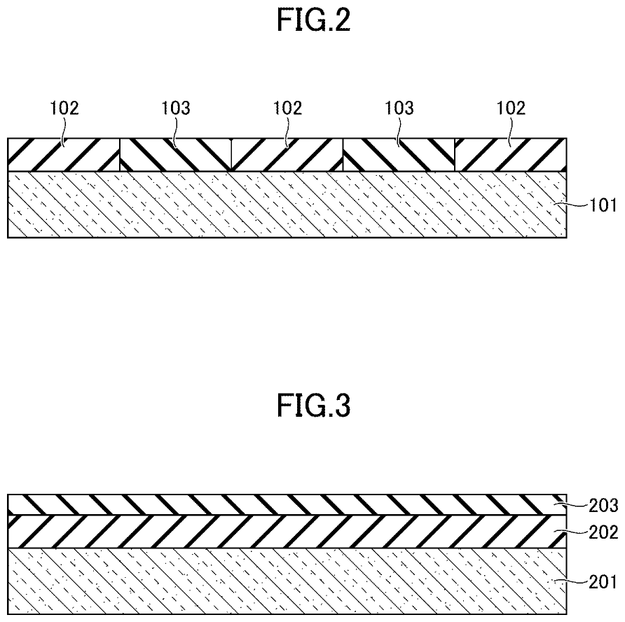

Referring to FIG. 1 and FIG. 2, a substrate-processing method according to an embodiment will be described. As illustrated in FIG. 1, the substrate-processing method according to the embodiment includes a providing step S1, a COR step S2, a purge step S3, a determination step S4, and a PHT step S5.

As illustrated in FIG. 2, the providing step S1 includes a substrate 101 including a silicon nitride film 102 and a silicon oxide film 103 that are on a surface of the substrate 101. The substrate 101 may be, for example, a silicon wafer. The silicon oxide film 103 may be, for example, a thermal oxide film famed through a thermal oxidation process.

The COR step S2 is performed after the providing step S1. The COR step S2 includes denaturing the surface layer of at least the silicon oxide film 103 into a reaction product through chemical oxide removal (COR) that performs etching chemically without generating a plasma. The COR step S2 includes, for example, supplying a gas mixture to the surface of the substrate 101, the gas mixture including fluorine-containing gas and basic gas. In this case, at least the silicon oxide film 103 and the gas mixture are reacted with each other to produce diammonium hexafluorosilicate [(NH₄)₂SiF₆]. The fluorine-containing gas may be, for example, hydrogen fluoride (HF) gas. The basic gas may be, for example, ammonia (NH₃) gas. The basic gas may be hydrazine (N₂H₄) gas.

The COR step S2 may include maintaining the temperature of the substrate 101 at a first temperature. For example, the first temperature may be 0° C. or higher and may be a temperature that is higher than room temperature. The first temperature may be 120° C. or lower and may be 80° C. or lower. When the first temperature is 120° C. or lower, the silicon oxide film 103 is readily etched.

The purge step S3 is performed after the COR step S2. The purge step S3 includes purging the surface of the substrate 101. In this case, the fluorine-containing gas, the basic gas, and the like that are adsorbed on the surface of the silicon nitride film 102 and the surface of the silicon oxide film 103 in the COR step S2 are removed. Also, reaction products that are produced in the COR step S2 are removed. Thereby, the surface of the silicon nitride film 102 and the surface of the silicon oxide film 103 become closer to the state before the COR step S2. The purge step S3 may include supplying inert gas to the surface of the substrate 101. The inert gas may be, for example, nitrogen (N₂) gas.

The time of a single purge step S3 is, for example, set to achieve the surface of the silicon nitride film 102 that is approximately the same as the state before the COR step S2. The time of a single purge step S3 may be, for example, longer than the time of a single COR step S2. The time of a single purge step S3 may be the same as the time of a single COR step S2, or may be shorter than the time of a single COR step S2. The time of a single purge step S3 may be, for example, 60 seconds or longer and 600 seconds or shorter.

The purge step S3 may include maintaining the temperature of the substrate 101 at the first temperature that is the same temperature as the temperature of the substrate 101 in the COR step S2. In this case, there is no need to change in temperature upon switching from the COR step S2 to the purge step S3, and thus productivity increases. Especially in use of a batch-type apparatus having a large heat capacity, it takes much time to change the temperature of the entire process chamber. Therefore, without any need to change in temperature upon switching from the COR step S2 to the purge step S3, productivity considerably increases. The batch-type apparatus will be described below.

The purge step S3 may be performed in the same process chamber as in the COR step S2. In this case, the COR step S2 and the purge step S3 can be performed continuously in a single process chamber, and productivity increases. The COR step S2 and the purge step S3 may be in a process chamber that houses a plurality of substrates 101 on shelves. In this case, the plurality of substrates 101 can be processed all at once, and productivity increases.

The determination step S4 is performed after the purge step S3. In the determination step S4, it is determined whether or not the COR step S2 and the purge step S3 have been performed a set number. When the number of these steps that have been performed does not reach the set number, the COR step S2 and the purge step S3 are performed again. Meanwhile, when the number of these steps that have been performed reaches the set number, the process proceeds to the PHT step S5. The set number in the determination step S4 may be two or more.

The PHT step S5 includes sublimating the reaction product with a post heat treatment (PHT) that performs heating with the substrate 101 being maintained at a second temperature that is higher than the first temperature. By performing the PHT step S5, it is possible to remove the reaction product remaining on the surface of the substrate 101. Note that, when the reaction product on the surface of the substrate 101 has already been removed at the purge step S3, the PHT step S5 may be omitted.

According to the substrate-processing method according to the embodiment as described above, the COR step S2 and the purge step S3 are alternatingly repeated. In this case, in the purge step S3, the surface of the silicon nitride film 102 and the surface of the silicon oxide film 103 become closer to the state before the COR step S2. When the surface of the silicon nitride film 102 has become closer to the state before the COR step S2, the silicon nitride film 102 does not become readily etched in the COR step S2 after the purge step S3. This is likely because etching of the silicon nitride film 102 starts after a predetermined time has passed from start of the COR step S2 (hereinafter referred to as “etching delay”). Meanwhile, when the surface of the silicon oxide film 103 has become closer to the state before the COR step S2, the silicon oxide film 103 becomes readily etched in the COR step S2 after the purge step S3. This is likely because the etching delay of the silicon oxide film 103 is shorter than the etching delay of the silicon nitride film 102 and because the etching rate of the silicon oxide film 103 decreases as the time of the COR step S2 becomes longer.

As such, by alternatingly repeating the COR step S2 and the purge step S3, the etching rate of the silicon nitride film 102 decreases while the etching rate of the silicon oxide film 103 increases in the COR step S2. As a result, the selectivity etching ratio of the silicon oxide film with respect to the silicon nitride film is increased.

Although the above-described embodiments have been described taking, as an example, the substrate 101 including the silicon nitride film 102 and the silicon oxide film 103 on the surface of the substrate 101, this is by no means a limitation. For example, as illustrated in FIG. 3, the above-described substrate-processing method is also applicable for removing a native oxide film 203 that has occurred on a silicon nitride film 202 on the surface of a substrate 201. In this case, the native oxide film 203 can be selectively removed with respect to the silicon nitride film 202.

[Substrate-Processing Apparatus]

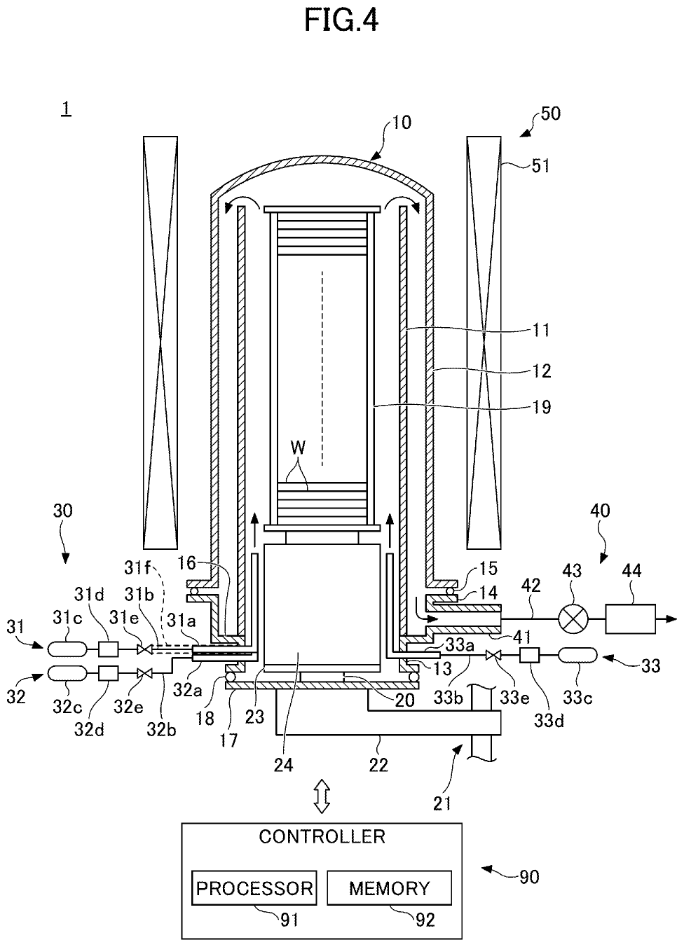

Referring to FIG. 4, a substrate-processing apparatus 1 according to an embodiment will be described. As illustrated in FIG. 4, the substrate-processing apparatus 1 is a batch-type apparatus configured to perform a process to a plurality of substrates W all at once. The substrate W is, for example, a semiconductor wafer. The process may include a film-forming process. The process may include an etching process.

The substrate-processing apparatus 1 includes a process chamber 10, a gas supply 30, an exhauster 40, a heater 50, and a controller 90.

The process chamber 10 can be reduced in internal pressure. The process chamber 10 is configured to house the substrates W. The process chamber 10 includes an inner tube 11 and an outer tube 12. The inner tube 11 has a cylindrical shape that is opened at the top and bottom ends thereof. The outer tube 12 has a cylindrical shape that includes the ceiling, is opened at the bottom end thereof, and surrounds the outer surface of the inner tube 11. The inner tube 11 and the outer tube 12 form a dual-tube structure in which the inner tube 11 and the outer tube 12 are coaxially disposed. The inner tube 11 and the outer tube 12 are formed of a heat-resistant material such as quartz or the like.

The bottom end of the process chamber 10 is hermetically supported by a manifold 13. The manifold 13 has a cylindrical shape. The manifold 13 is formed of, for example, stainless steel. At the top end of the manifold 13, a flange 14 is formed. The bottom end of the outer tube 12 is disposed on and supported by the flange 14. Between the flange 14 and the bottom end of the outer tube 12, a seal member 15 such as an O-ring is provided, thereby hermetically maintaining the inner space of the outer tube 12.

The inner wall of the manifold 13 is provided with an annular support 16. The bottom end of the inner tube 11 is disposed on and supported by the support 16.

To the opening at the bottom end of the manifold 13, a cover 17 is hermetically attached via a seal member 18 such as an O-ring or the like, thereby hermetically sealing the opening at the bottom end of the process chamber 10; i.e., the opening of the manifold 13. The cover 17 is formed of, for example, stainless steel.

At the center of the cover 17, a penetrating rotating shaft 20 that rotatably supports a boat 19 via an unillustrated magnetic fluid seal is provided. The lower portion of the rotating shaft 20 is rotatably supported by an arm 22 of an ascending and descending mechanism 21 formed of a boat elevator.

At the top end of the rotating shaft 20, a rotating plate 23 is provided. On the rotating plate 23, the boat 19 is placed via a warming stage 24 formed of quartz. Therefore, by ascending and descending the arm 22 of the ascending and descending mechanism 21, the cover 17 and the boat 19 move upward and downward together, and thereby, the boat 19 can be inserted into and released from the process chamber 10. The boat 19 can be housed in the process chamber 10. The boat 19 approximately horizontally retains a plurality of (e.g., from 50 through 150) substrates W at intervals in an up-and-down direction.

The gas supply 30 is configured to introduce various process gases into the process chamber 10. The gas supply 30 includes a hydrogen fluoride supply 31, an ammonia supply 32, a nitrogen supply 33, and an unillustrated film-forming gas supply.

The hydrogen fluoride supply 31 includes: a hydrogen fluoride supply tube 31a inside the process chamber 10; and a hydrogen fluoride supply path 31b outside the process chamber 10. The hydrogen fluoride supply path 31b sequentially includes a hydrogen fluoride source 31c, a mass flow controller 31d, and a hydrogen fluoride valve 31e from upstream to downstream of a gas flow direction. Thereby, hydrogen fluoride gas of the hydrogen fluoride source 31c is controlled by the hydrogen fluoride valve 31e in tams of the time of supply, and is also adjusted by the mass flow controller 31d to a predetermined flow rate. The hydrogen fluoride gas flows into the hydrogen fluoride supply tube 31a through the hydrogen fluoride supply path 31b, and is discharged from the hydrogen fluoride supply tube 31a into the process chamber 10. The hydrogen fluoride gas is one example of the fluorine-containing gas.

The ammonia supply 32 includes: an ammonia supply tube 32a inside the process chamber 10; and an ammonia supply path 32b outside the process chamber 10. The ammonia supply path 32b sequentially includes an ammonia source 32c, a mass flow controller 32d, and an ammonia valve 32e from upstream to downstream of a gas flow direction. Thereby, ammonia gas of the ammonia source 32c is controlled by the ammonia valve 32e in terms of the time of supply, and is also adjusted by the mass flow controller 32d to a predetermined flow rate. The ammonia gas flows into the ammonia supply tube 32a through the ammonia supply path 32b, and is discharged from the ammonia supply tube 32a into the process chamber 10. The ammonia gas is one example of the basic gas.

The nitrogen supply 33 includes: a nitrogen supply tube 33a inside the process chamber 10; and a nitrogen supply path 33b outside the process chamber 10. The nitrogen supply path 33b sequentially includes a nitrogen source 33c, a mass flow controller 33d, and a nitrogen valve 33e from upstream to downstream of a gas flow direction. Thereby, nitrogen gas of the nitrogen source 33c is controlled by the nitrogen valve 33e in terms of the time of supply, and is also adjusted by the mass flow controller 33d to a predetermined flow rate. The nitrogen gas flows into the nitrogen supply tube 33a through the nitrogen supply path 33b, and is discharged from the nitrogen supply tube 33a into the process chamber 10. The nitrogen gas is one example of the inert gas.

The gas supply tubes (the hydrogen fluoride supply tube 31a, the ammonia supply tube 32a, and the nitrogen supply tube 33a) are famed of, for example, quartz. The gas supply tubes are fixed to the manifold 13. The gas supply tubes each extend in the form of a straight line along a vertical direction at a position near the inner tube 11, and bend in an L shape to horizontally extend in the manifold 13, thereby penetrating the manifold 13. The gas supply tubes are provided side by side along a circumferential direction of the inner tube 11. The gas supply tubes are formed at the same height. The gas supply tubes each have an opening at a tip thereof that is located in the inner tube 11, and discharge gas from the opening upward into the process chamber 10.

A heater 31f is attached to the hydrogen fluoride supply tube 31a and the hydrogen fluoride supply path 31b. The heater 31f is configured to heat hydrogen fluoride flowing through the hydrogen fluoride supply tube 31a and the hydrogen fluoride supply path 31b, and suppresses corrosion of the hydrogen fluoride supply tube 31a and the hydrogen fluoride supply path 31b due to hydrogen fluoride gas. The heater 31f includes, for example, a tube heater, a cartridge heater, or both thereof. The heater 31f may be attached to only one of the hydrogen fluoride supply tube 31a and the hydrogen fluoride supply path 31b.

The film-forming gas supply may have the same configuration as the other supplies (the hydrogen fluoride supply 31, the ammonia supply 32, and the nitrogen supply 33). Similar to the other supplies, the film-forming gas supply includes a film-forming gas supply tube, a film-forming gas supply path, a film-forming gas source, a mass flow controller, and a film-forming gas valve.

The gas supply 30 may mix two or more types of gas together and discharge the mixed gas from a single supply tube. The gas supply tubes (the hydrogen fluoride supply tube 31a, the ammonia supply tube 32a, the nitrogen supply tube 33a, and the film-forming gas supply tube) may be different from each other in shape and arrangement. The gas supply 30 may be configured to supply another gas, in addition to the hydrogen fluoride gas, the ammonia gas, the nitrogen gas, and the film-forming gas.

The exhauster 40 is configured to exhaust gas that is exhausted from the interior of the inner tube 11 and exhausted from an exhaustion port 41 through a space between the inner tube 11 and the outer tube 12. The exhaustion port 41 is formed in the side wall of the upper portion of the manifold 13 and above the support 16. An exhaustion path 42 is connected to the exhaustion port 41. The exhaustion path 42 sequentially includes a pressure adjusting valve 43 and a vacuum pump 44 from upstream to downstream of a gas flow direction. The exhauster 40 operates the pressure adjusting valve 43 and the vacuum pump 44 based on the operation of the controller 90, and adjusts the pressure in the process chamber 10 with the pressure adjusting valve 43 while suctioning gas in the process chamber 10 with the vacuum pump 44.

The heater 50 includes a cylindrical heater 51 that surrounds the outer tube 12 outside in a radial direction of the outer tube 12. The heater 51 is configured to heat the entire side periphery of the process chamber 10, thereby heating the substrates W housed in the process chamber 10.

As the controller 90, a computer including one or more processors 91, a memory 92, an unillustrated input-output interface, and an electronic circuit is applicable. The processor 91 is a combination of one or more of, for example, CPU, ASIC, FPGA, and a circuit made of a plurality of discrete semiconductors. The memory 92 includes volatile memories and non-volatile memories (e.g., compact discs, DVDs, hard disks, flash memories, and the like) and stores a program for driving the substrate-processing apparatus 1 and a recipe of, for example, process conditions for a substrate process. By executing the program and recipe stored in the memory 92, the processor 91 controls the components of the substrate-processing apparatus 1, thereby implementing the below-described method.

[Operations of Substrate-Processing Apparatus]

Operations in performing the above-described substrate-processing method by the substrate-processing apparatus 1 will be described.

First, the controller 90 controls the ascending and descending mechanism 21 to: transfer the boat 19, retaining a plurality of substrates W, into the process chamber 10; and hermetically seal the opening at the bottom end of the process chamber 10 with the cover 17 for hermetical closing. Each of the substrates W may be a substrate 101 including the silicon nitride film 102 and the silicon oxide film 103 that are on a surface of the substrate 101.

Subsequently, the controller 90 controls the gas supply 30, the exhauster 40, and the heater 50 so as to perform the COR step S2. Specifically, first, the controller 90 controls the exhauster 40 so as to reduce the internal pressure of the process chamber 10 to a predetermined pressure, and controls the heater 50 so as to adjust and maintain the temperature of the substrate W to and at the first temperature. Next, the controller 90 controls the gas supply 30 so as to supply hydrogen fluoride gas and ammonia gas into the process chamber 10.

Subsequently, the controller 90 controls the gas supply 30, the exhauster 40, and the heater 50 so as to perform the purge step S3. Specifically, the controller 90 controls the exhauster 40 so as to vacuum the process chamber 10 and controls the heater 50 so as to maintain the temperature of the substrate W at the first temperature. In this state, the controller 90 controls the gas supply 30 so as to supply nitrogen gas into the process chamber 10.

The controller 90 alternatingly repeats the COR step S2 and the purge step S3 until the number of the COR step S2 and the purge step S3 that have been performed reaches a set number.

After the number of the COR step S2 and the purge step S3 that have been performed has reached the set number, the controller 90 controls the gas supply 30, the exhauster 40, and the heater 50 so as to perform the PHT step S5. Specifically, the controller 90 controls the heater 50 so as to heat the substrate W to the second temperature and sublimate diammonium hexafluorosilicate. Thereby, it is possible to selectively etch and remove the silicon oxide film 103 while leaving the silicon nitride film 102 remaining.

Subsequently, the controller 90 increases the internal pressure of the process chamber 10 to the atmospheric pressure and decreases the internal temperature of the process chamber 10 to a dischargeable temperature. Then, the controller 90 controls the ascending and descending mechanism 21 so as to discharge the boat 19 from the process chamber 10. Through the above-described procedure, the process for the plurality of substrates W ends.

### EXAMPLES

### Example 1

Example 1 will be described. Example 1 was performed for confirming that the substrate-processing method according to the embodiment increases the selectivity etching ratio of the silicon oxide film with respect to the silicon nitride film.

In Example 1, a substrate including a silicon oxide film on the surface thereof and a substrate including a silicon nitride film on the surface thereof were provided. Then, the provided substrates were placed in the process chamber 10 of the substrate-processing apparatus 1, and were processed in Conditions 1A to 1D described below. In Example 1, a thermal oxide film was used as the silicon oxide film. In Example 1, thicknesses of the silicon oxide film and the silicon nitride film before and after the process were measured with a spectroscopic ellipsometer, and the difference between the thicknesses thereof before and after the process was obtained, thereby calculating etching amounts of the silicon oxide film and the silicon nitride film.

(Condition 1A)

In Condition 1A, the COR step S2 and the PHT step S5 were performed without performing the purge step S3 and the determination step S4. In Condition 1A, the time of the COR step S2 was set to 180 seconds.

(Condition 1B)

In Condition 1B, the COR step S2, the purge step S3, the determination step S4, and the PHT step S5 were performed. In Condition 1B, the time of a single COR step S2 was set to 30 seconds, the time of a single purge step S3 was set to 60 seconds, and the set number in the determination step S4 was set to six. The total time of the COR step S2 in Condition 1B is the same as the time of the COR step S2 in Condition 1A (i.e., 180 seconds).

(Condition 1C)

In Condition 1C, the COR step S2, the purge step S3, the determination step S4, and the PHT step S5 were performed. In Condition 1C, the time of a single COR step S2 was set to 10 seconds, the time of a single purge step S3 was set to 60 seconds, and the set number in the determination step S4 was set to 18. The total time of the COR step S2 in Condition 1C is the same as the time of the COR step S2 in Condition 1A (i.e., 180 seconds).

(Condition 1D)

In Condition 1D, the COR step S2, the purge step S3, the determination step S4, and the PHT step S5 were performed. In Condition 1D, the time of a single COR step S2 was set to 30 seconds, the time of a single purge step S3 was set to 600 seconds, and the set number in the determination step S4 was set to six. The total time of the COR step S2 in Condition 1D is the same as the time of the COR step S2 in Condition 1A (i.e., 180 seconds).

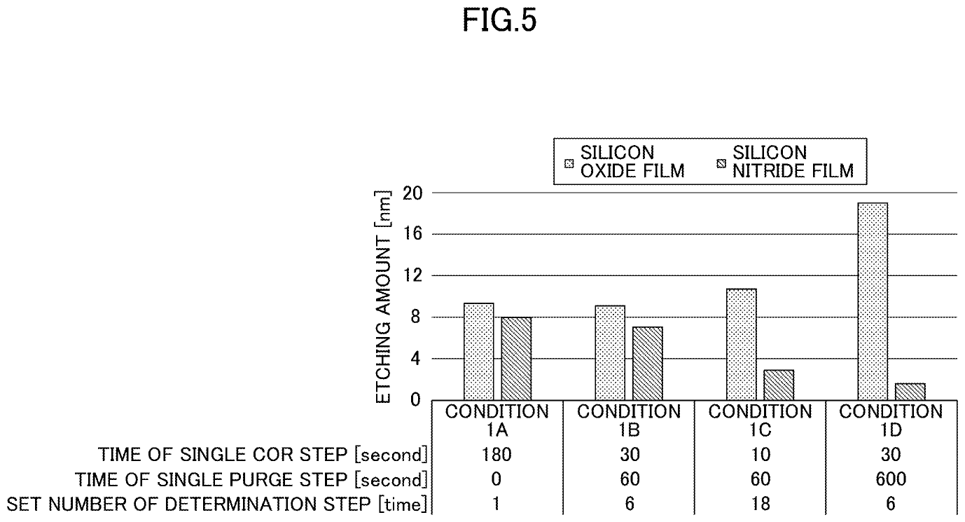

FIG. 5 is a graph illustrating evaluation results of etching amounts. FIG. 5 illustrates the etching amounts [nm] of the silicon oxide film and the silicon nitride film that were etched in Condition 1A, Condition 1B, Condition 1C, and Condition 1D.

As illustrated in FIG. 5, the etching amount of the silicon nitride film is smaller in Condition 1B, Condition 1C, and Condition 1D than in Condition 1A. This result indicates that the selectivity etching ratio of the silicon oxide film with respect to the silicon nitride film is increased by alternatingly repeating the COR step S2 and the purge step S3.

As illustrated in FIG. 5, the etching amount of the silicon oxide film is greater and the etching amount of the silicon nitride film is smaller in Condition 1C than in Condition 1B. This result indicates that the selectivity etching ratio of the silicon oxide film with respect to the silicon nitride film is increased by shortening the time of a single COR step S2 and increasing the set number in the determination step S4.

As illustrated in FIG. 5, the etching amount of the silicon oxide film is greater and the etching amount of the silicon nitride film is smaller in Condition 1D than in Condition 1B. This result indicates that the selectivity etching ratio of the silicon oxide film with respect to the silicon nitride film is increased by extending the time of a single purge step S3.

### Example 2

In Example 2, a relationship between the time of the COR step S2 and the etching amount was confirmed. In Example 2, a substrate including a silicon oxide film on the surface thereof and a substrate including a silicon nitride film on the surface thereof were provided. Then, the provided substrates were placed in the process chamber 10 of the substrate-processing apparatus 1, and were subjected to the COR step S2. In Example 2, the process was performed under three conditions in which the time of the COR step S2 was different. In Example 2, a thermal oxide film was used as the silicon oxide film. In Example 2, the etching amounts of the silicon oxide film and the silicon nitride film were calculated in the same manner as in Example 1.

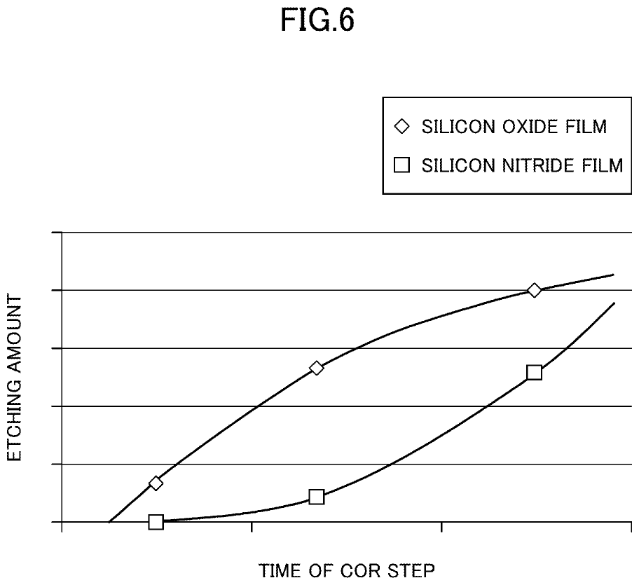

FIG. 6 is a view illustrating a relationship between the time of the COR step S2 and the etching amount. In FIG. 6, the horizontal axis indicates the time of the COR step S2 and the vertical axis indicates the etching amount. In FIG. 6, a rhombus mark indicates the etching amount of the silicon oxide film and a square mark indicates the etching amount of the silicon nitride film.

As illustrated in FIG. 6, the etching rate of the silicon oxide film is lower as the time is longer, while the etching rate of the silicon nitride film is greater as the time is longer. From this result, the time of a single COR step S2 is preferably the time it takes to make the etching rate of the silicon nitride film lower than the etching rate of the silicon oxide film. Thereby, it is possible to increase the selectivity etching ratio of the silicon oxide film with respect to the silicon nitride film. The time of a single COR step S2 is preferably a time equal to or shorter than ⅓ the time it takes to make the etching amount of the silicon nitride film equal to the etching amount of the silicon oxide film, and more preferably a time equal to or shorter than 1/5 the time it takes to make the etching amount of the silicon nitride film equal to the etching amount of the silicon oxide film. Thereby, it is possible to increase the selectivity etching ratio of the silicon oxide film with respect to the silicon nitride film. Note that, the etching rate may be the slope of a curve in FIG. 6.

As illustrated in FIG. 6, the etching delay occurs when the silicon oxide film and the silicon nitride film are etched in the COR step S2, and the etching delay is longer in the silicon nitride film than in the silicon oxide film. From this result, the time of a single COR step S2 is preferably a time that is longer than the etching delay in the silicon oxide film and shorter than the etching delay in the silicon nitride film. Thereby, it is possible to selectively etch the silicon oxide film without etching the silicon nitride film. As a result, the selectivity etching ratio of the silicon oxide film with respect to the silicon nitride film is particularly increased.

According to the present disclosure, it is possible to increase the selectivity etching ratio of the silicon oxide film with respect to the silicon nitride film.

It should be understood that the embodiments disclosed herein are illustrative and not restrictive in all respects. Various omissions, substitutions, and changes may be made to the above-described embodiments without departing from the scope of claims recited and the spirit of the disclosure.

Although the above-described embodiments have been described in the case where the substrate-processing apparatus is a batch-type apparatus configured to perform a process to a plurality of substrates all at once, the present disclosure is not limited to this. For example, the substrate-processing apparatus may be a single wafer processing apparatus configured to process a plurality of substrates one by one.

What is claimed is:

1. A substrate-processing method, comprising:
a) providing a substrate including a silicon oxide film on a surface of the substrate;
b) supplying a gas mixture to the surface of the substrate, thereby etching the silicon oxide film, the gas mixture including fluorine-containing gas and basic gas;
c) purging the surface of the substrate; and
d) alternatingly repeating b) and c).

2. The substrate-processing method according to claim 1, wherein in b) and c), the substrate is maintained at a same temperature.

3. The substrate-processing method according to claim 1, wherein b) and c) are performed in the same process chamber.

4. The substrate-processing method according to claim 2, wherein b) and c) are performed in the same process chamber.

5. The substrate-processing method according to claim 3, wherein c) includes supplying inert gas into the process chamber while vacuuming the process chamber.

6. The substrate-processing method according to claim 4, wherein c) includes supplying inert gas into the process chamber while vacuuming the process chamber.

7. The substrate-processing method according to claim 3, wherein the process chamber houses a plurality of substrates on shelves, the plurality of substrates each being the substrate as recited in claim 1.

8. The substrate-processing method according to claim 4, wherein the process chamber houses a plurality of substrates on shelves, the plurality of substrates each being the substrate as recited in claim 1.

9. The substrate-processing method according to claim 1, wherein the substrate further includes a silicon nitride film on the surface, and
switching from b) to c) is performed before start of etching of the silicon nitride film.

10. The substrate-processing method according to claim 2, wherein the substrate further includes a silicon nitride film on the surface, and
switching from b) to c) is performed before start of etching of the silicon nitride film.

11. The substrate-processing method according to claim 1, wherein the fluorine-containing gas is hydrogen fluoride gas, and the basic gas is ammonia gas.

12. The substrate-processing method according to claim 2, wherein the fluorine-containing gas is hydrogen fluoride gas, and the basic gas is ammonia gas.

13. The substrate-processing method according to claim 1, wherein the silicon oxide film is a thermal oxide film.

14. The substrate-processing method according to claim 2, wherein the silicon oxide film is a thermal oxide film.

15. The substrate-processing method according to claim 1, further comprising, after d): heating the substrate to a temperature that is higher than in b).

16. The substrate-processing method according to claim 2, further comprising, after d): heating the substrate to a temperature that is higher than in b).

17. A substrate-processing apparatus, comprising:
a process chamber;
a gas supply configured to supply gas into the process chamber; and
a controller, wherein
the controller is configured to perform
a) placing, in the process chamber, a substrate including a silicon oxide film on a surface of the substrate,
b) supplying a gas mixture into the process chamber in which the substrate is placed, thereby etching the silicon oxide film, the gas mixture including fluorine-containing gas and basic gas,
c) purging the process chamber in which the substrate is placed, and
d) alternatingly repeating b) and c).
